(19) United States
(12) Patent Application Publication
(10) Pub. No.: US 2008/0001204 A1
(43) Pub. Date: Jan. 3, 2008

(54) Non-volatile memory device and method for fabricating the same

(75) Inventors: Yong-Kyu Lee, Gwacheon-si (KR); Hee-Seog Jeon, Hwaseong-si (KR); Jeong-Uk Han, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 11/647,711

(22) Filed: Dec. 29, 2006

(30) Foreign Application Priority Data
Jun. 29, 2006 (KR) 10-2006-0059132

(51) Int. Cl. H01L 29/76

(52) U.S. Cl. 257/314

(57) ABSTRACT

A non-volatile memory device and a method for fabricating the non-volatile memory device. The non-volatile memory device includes a memory cell located in a first conductive region and has a memory transistor, a selection transistor and a high voltage switching device located in a second conductive region close to the first conductive region. The memory cell is controlled by the high voltage switching device. At least one of the high voltage switching device, the memory transistor, or the selection transistor has a recessed channel region.

### CROSS-REFERENCE TO RELATED PATENT APPLICATIONS

This application claims priority to Korean Patent Application No. 10-2006-0059132, filed on 29 Jun. 2006, in the Korean Intellectual Property Office, the disclosure of which is incorporated herein in its entirety by reference.

### BACKGROUND OF THE INVENTION

1. Technical Field

The present disclosure relates to a memory device, and more particularly, to a non-volatile memory device and a method for fabricating the same.

2. Discussion of the Related Art

Non-volatile memory devices are capable of retaining data even when the power supply is discontinued, unlike DRAM (dynamic random access memory) or SRAM (static random access memory) devices. An EEPROM is a typical non-volatile memory device that is electrically programmable and erasable by applying various voltages to a gate thereof.

The EEPROM may include a memory cell consisting of 1 byte comprising 8 unit bits and a high voltage switching device to select the memory cell. To keep pace with the recent trend of the high integration of a semiconductor devices, the EEPROM having the above characteristics is formed in a relatively smaller area without deterioration of the characteristics of the device.

### SUMMARY OF THE INVENTION

Exemplary embodiments of the present invention provide a non-volatile memory device which reduces an occupied area without the deterioration of the characteristics of the device.

Exemplary embodiments of the present invention provide a method for fabricating a non-volatile memory device that is formed on a relatively small area without the deterioration of the device characteristics.

According to an exemplary embodiment of the present invention, a non-volatile memory device comprises a memory cell located in a first conductive region. The device also includes a memory transistor, a selection transistor, and a high voltage switching device located in a second conductive region close to the first conductive region. The memory cell is controlled by a predetermined unit. At least one of the high voltage switching device, the memory transistor, or the selection transistor has a recessed channel region.

Each of the high voltage switching device, the memory transistor, and the selection transistor comprise a source/drain region. The recessed channel region is recessed deeper than the junction depth of the source/drain region.

A gate insulation film is formed above the recessed channel region. The film is comprised of a combination of an oxidation film and a deposition film. The gate insulation film formed above the recessed channel region has a substantially uniform thickness.

The memory transistor comprises a stack gate structure including a gate insulation film, a float gate, an inter-gate insulation film and a control gate. Alternatively, the memory transistor may comprise a single gate structure including an electric charge storage insulation film and a gate.

The first and second conductive regions are comprised of a conductive well or a semiconductor substrate. The high voltage switching device is a PMOS (p-channel metal-oxide-semiconductor), an NMOS (n-channel metal-oxide-semiconductor), or a CMOS (complementary metal-oxide-semiconductor) transistor.

According to an exemplary embodiment of the present invention, a non-volatile memory device comprises a cell block having a plurality of memory cells arranged in units of bytes located in a first conductive well located in a first conductive substrate. Each memory cell has a memory transistor, a selection transistor, and a high voltage switching device located in a second conductive well close to the first conductive well. The memory cells are controlled by a predetermined unit. At least one of the high voltage switching device, the memory transistor, or the selection transistor has a recessed channel region.

Each of the high voltage switching device, the memory transistor, and the selection transistor comprise a source/drain region. The recessed channel region is recessed deeper than the junction depth of the source/drain region.

A gate insulation film is formed above the recessed channel region. The film is comprised of a combination of an oxidation film and a deposition film. The gate insulation film formed above the recessed channel region has a substantially uniform thickness.

The memory transistor comprises a stack gate structure consisting of a gate insulation film, a float gate, an inter-gate insulation film and a control gate. Alternatively, the memory transistor may comprise a single gate structure including an electric charge storage insulation film and a gate.

The high voltage switching device is a PMOS, an NMOS, or a CMOS transistor.

According an exemplary embodiment of the present invention, a method for fabricating a non-volatile memory device comprises forming a memory cell having a memory transistor and a selection transistor in a first conductive region. A high voltage switching device controls the memory cell by a predetermined unit in a second conductive region close to the first conductive region. At least one of the high voltage switching device, the memory transistor, or the selection transistor has a recessed channel region.

A gate insulation film is formed above the recessed channel region by a repeated combination of an oxidation method and a deposition method. The oxidation method is a thermal oxidation method and the deposition method is a chemical vapor deposition method.

An oxidation film formed above the recessed channel region has a substantially uniform thickness.

### BRIEF DESCRIPTION OF THE DRAWINGS

The above and other features and aspects of exemplary embodiments of the present invention will become more apparent by describing in detail preferred embodiments with reference to the attached drawings in which:

FIG. 1 is a circuit diagram showing a part of a non-volatile memory device according to an exemplary embodiment of the present invention;

FIGS. 2 and 3 are circuit diagrams showing the voltage conditions for programming and erasing the non-volatile memory device of FIG. 1;

FIG. 4 is a cross-sectional view showing a part of the non-volatile memory device of FIG. 1;

FIGS. 5A and 5B are cross-sectional views showing the gate insulation film located in the upper portion of the recessed channel region of the non-volatile memory device of FIG. 1;

FIG. 6 is a cross-sectional view showing a part of a non-volatile memory device according to another exemplary embodiment of the present invention;

FIGS. 7 through 13 are cross-sectional views showing parts of non-volatile memory devices according to exemplary embodiments of the present invention;

FIGS. 14 through 17 are cross-sectional views of the intermediate structures which are sequentially arranged in the process order according to a method for fabricating a non-volatile memory device according to an exemplary embodiment of the present invention;

FIGS. 18 and 19 are cross-sectional views of the intermediate structures which are sequentially arranged in the process order according to a method for fabricating a non-volatile memory device according to another exemplary embodiment of the present invention; and

FIGS. 20 through 27 are cross-sectional views of the intermediate structures which are sequentially arranged in the process order according to a method for fabricating a non-volatile memory device according to another exemplary embodiment of the present invention.

### DETAILED DESCRIPTION OF THE EXEMPLARY EMBODIMENTS

Exemplary embodiments of the present invention will be clearer by referring to the accompanying drawings and the description below. However, the present invention is not limited to the below-described exemplary embodiments. Throughout the specification, like reference numerals in the drawings denote like elements.

Although the words of “first,” “second,” etc. are used to described various constituent elements, regions, wiring, layers and/or sections, these constituent elements, regions, wiring, layer and/or sections are not limited by these words. The words are used merely to distinguish one constituent element, region, wiring, layer and/or sections from other constituent elements, regions, wiring, layers and/or sections. Thus, the first constituent element, first region, first wiring, first layer and/or first section which are shown below may be the second constituent element, second region, second wiring, second layer and/or second section within the technical concept of the present disclosure.

The spatially relative words of “below,” “beneath,” “lower,” “above,” or “upper” can be used to easily describe the correlation between one constituent element from other constituent element as shown in the drawings. When used in addition to a direction shown in the drawings, the spatially relative words should be understood to include different directions of the constituent elements. For example, when a constituent element indicated on the drawing is turned over, the constituent element described to be below or beneath other constituent element may be positioned above or on an upper side of the other constituent element. Thus, the exemplary words of “below” or “beneath” can include both down and up directions. The constituent element can be arranged in a different direction and accordingly the spatially relative words can be interpreted according to the direction.

Furthermore, the words of the “first conductive type” and the “second conductive type” indicate conductive types opposite to each other such as P type or N type. The below-described embodiments include an embodiment complementary thereto.

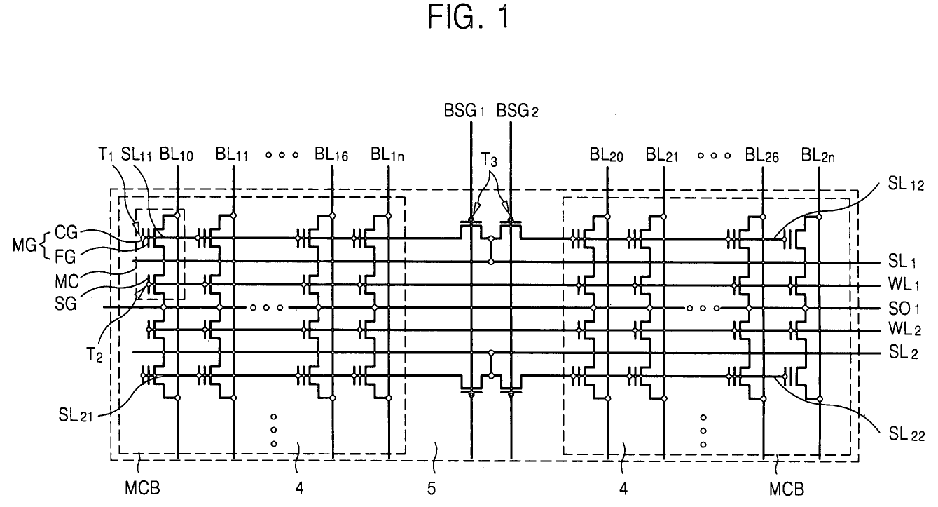

A non-volatile memory device according to an exemplary embodiment of the present invention will be described with reference to FIG. 1. FIG. 1 is a circuit diagram showing a part of a non-volatile memory device according to an exemplary embodiment of the present invention. In detail, FIG. 1 is a circuit diagram showing a part of an EEPROM device using a 2-transistor flash cell.

As shown in FIG. 1, the non-volatile memory device according to an exemplary embodiment of the present invention includes a memory cell MC and a high voltage switching device T₃ selecting the memory cell MC. The memory cell MC includes two transistors, for example, a memory transistor T₁ and a selection transistor T₂. The memory transistor T₁ keeps data in a level of “1” or “0” while the selection transistor T₂ selects a memory bit. The memory transistor T₁ includes a stack gate of a memory gate MG that includes a floating gate FG and a control gate CG, or includes a single gate although it is not shown. The selection transistor T₂ includes a selection gate SG. A plurality of memory cells MC comprise a memory cell block MCB.

The control gates CG of the memory transistors T₁ located in the memory cell block MCB are connected at each row by a local sense line SLᵢₙ, for example, SL₁₁, SL₁₂, SL₂₁, and SL₂₂. The selection gates SG of the selection transistors T₂ are connected at each row by a word line WLᵢ, for example, WL₁ and WL₂. Also, a plurality of the selection transistors T₂ are connected to a common source line SOᵢ, for example, SO₁. The common source line SOᵢ can be provided for each row, each column, each sector, or the whole memory. In FIG. 1, not all connections of the common source lines SOᵢ are shown.

A high voltage switching device T₃ is located around the memory cell block MCB. The high voltage switching device T₃ programs and erases the memory cell MC by one byte comprising a unit of 8 bits. The high voltage switching device T₃ comprises a switching transistor at every one-byte memory cell to embody the byte selection operation of the memory cell MC. The high voltage switching device T₃ divides a global sense line SLᵢ, for example, SL₁ and SL₂, into the local sense lines SLᵢₙ, for example, SL₁₁, SL₁₂, SL₂₁, and SL₂₂, extending over one byte or word, and addressed by a byte selection gate line BSGᵢ, for example, BSG₁ and BSG₂, extending parallel to a bit line BLᵢ.

The high voltage switching device T₃ is located in a conductive region different from the memory cell MC. For example, when the memory cell MC is located in a first conductive region 4, the high voltage switching device T₃ is located in a second conductive region 5. The conductive region may be a conductive well or a semiconductor substrate. The high voltage switching device T₃ may be, for example, a PMOS, NMOS, or CMOS transistor.

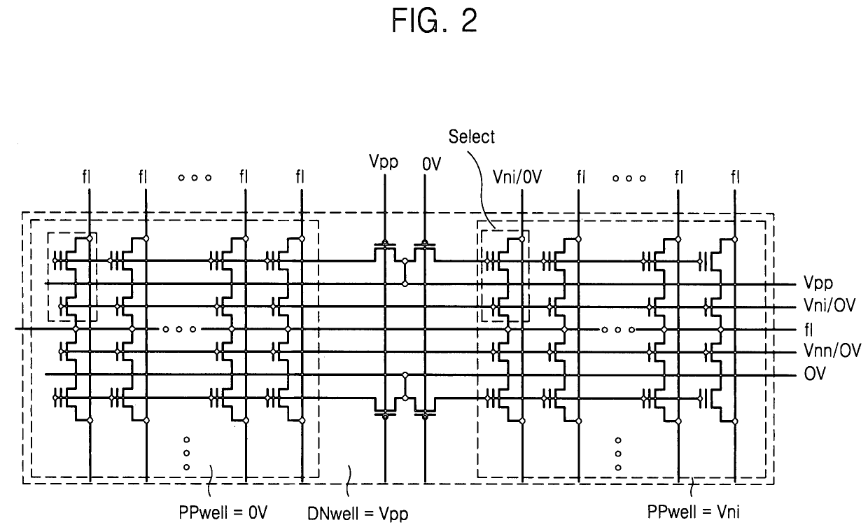

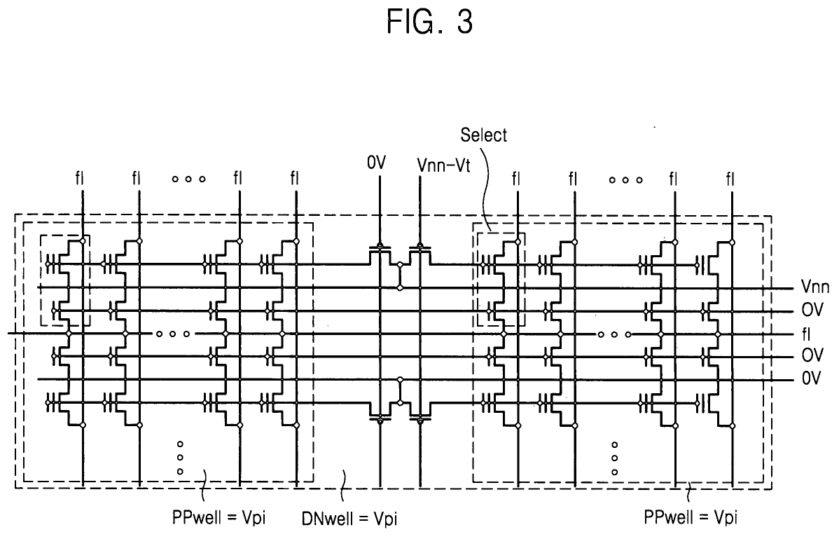

The high voltage switching device T₃ will be described in detail with reference to FIGS. 2 and 3. FIGS. 2 and 3 are circuit diagrams showing the voltage conditions for programming and erasing the non-volatile memory device of FIG. 1. Referring to FIGS. 2 and 3, when the memory cell MC is located in a P-type well (4 of FIG. 1), for example, a pocket P-type well, the high voltage switching device T₃ is located in an N-type well (5 of FIG. 1), for example, a deep N-type well (DNwell). The high voltage switching device T₃ may be a PMOS transistor.

When the high voltage switching device T₃ is provided in form of a PMOS transistor, during programming, a positive high voltage Vₚₚ applied to the high voltage switching device T₃ is applied to the memory gate MG of the one-byte memory cell through the byte selection gate line BSG₁ or BSG₂. During erasure, a negative high voltage Vₙₙ is applied to the memory gate of the one-byte memory cell through the byte selection gate line BSG₁ or BSG₂. However, during the erasure, the high voltage switching device T₃ is a PMOS transistor and a threshold voltage Vₜₕ of the high voltage switching device T₃ is increased by a body effect due to the positive voltage caused in the deep N-type well DNwell. Thus, to transmit the negative high voltage Vₙₙ to the word line WL, Vₙₙ-Vₜ (body effect) is applied to the high voltage switching device T₃ as shown in Table 1 below.

Since a high voltage needed for programming and erasing of the memory cell MC in an F-N (Fowler-Nordheim) tunneling method is applied to the high voltage switching device T₃, the high voltage switching device T₃ is formed of a high voltage transistor having a gate relatively longer than that of a low voltage device.

TABLE 1

| | BL | SL | WL | SO | NSG | PPwell | DNwell |
|---|---|---|---|---|---|---|---|
| PROGRAM | | | | | | | |
| Selected | Vₙᵢ/0 | Vₚₚ | Vₙᵢ/0 | fl | 0 | Vₙᵢ | Vₚₚ |
| Not | fl | 0 | Vₙₙ/0 | fl | Vₚₚ | 0 | Vₚₚ |
| selected | | | | | | | |
| ERASE | | | | | | | |
| Selected | Fl | Vₙₙ | 0 | fl | Vₙₙ-Vₜ | Vₚᵢ | Vₚᵢ |
| Not | fl | 0 | 0 | fl | 0 | 0 | Vₚᵢ |
| selected | | | | | | | |
| READ | | | | | | | |
| Selected | V_{cc}/0 | Vᵣ | Vᵣ | 0 | 0 | 0 | V_{cc} |
| Not | 0 | Vᵣ | 0 | 0 | V_{cc} | 0 | V_{cc} |
| selected | | | | | | | |

(Vₙᵢ: negative intermediate voltage, Vₚᵢ: positive intermediate voltage, V_{cc}: collector voltage, Vᵣ: read voltage, and fl: floating)

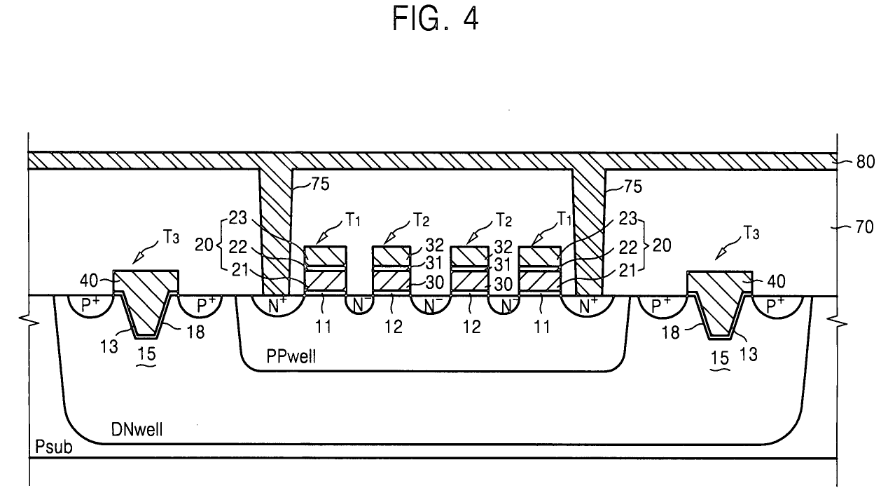

A non-volatile memory device according to an embodiment of the present invention will be described with reference to FIG. 4. FIG. 4 is a cross-sectional view showing a part of the non-volatile memory device of FIG. 1. According to an exemplary embodiment, the first conductive type is a P-type and the second conductive type is an N-type. However, other conductive types may be used.

As shown in FIG. 4, a memory cell of the non-volatile memory device according to the exemplary embodiment is formed in the pocket P-type well PPwell that is formed on a P-type semiconductor substrate Psub, to comprise the memory cell block. The memory cell includes the memory transistor T₁ and the selection transistor T₂.

The memory transistor T₁ includes a memory gate 20 of a stack gate structure and a source/drain region N⁺ or N⁻ located in the semiconductor substrate Psub. The source/drain region is arranged on two side walls of the memory gate 20. The memory gate 20 comprises a floating gate 21 formed on the pocket P-type well PPwell, a inter-gate insulation film 22 formed on the floating gate 21, and a control gate 23 formed on the inter-gate insulation film 22.

The floating gate 21 and the control gate 23 may be comprised of, for example, doped polysilicon, and the inter-gate insulation film 22 may be comprised of, for example, a deposition layer of a silicon oxide (SiOx) film, a silicon nitride (SiNx) film, and/or a silicon oxide (SiOx) film.

Although it is not shown, the source/drain region may be comprised of a lightly doped drain (LDD) type in an N⁻ impurity region and an N⁺ impurity region or a mask island double diffused drain (DDD) type formed by limiting the N⁺ impurity region in the N⁻ impurity region. However, other types of source/drain regions can be used.

A gate insulation film 11 is interposed between the pocket P-type well PPwell and the float gate 21. The gate insulation film 11 includes a relatively thin tunneling area. The tunneling area can have a thickness capable of F-N tunneling during the program and erasure of the memory cell MC. Electric charges are moved to the float gate 21 through the tunneling area. The gate insulation film 11 can be comprised of a combination of an oxide film and a deposition film.

An interlayer insulation film 70 having a contact hole 75 that exposes the drain region N⁺ is provided. A bit line 80 is electrically connected to the drain region N⁺ through the contact hole 75.

The selection transistor T₂ serially connected to the memory transistor T₁ is located in the pocket P-type well PPwell. The selection transistor T₂ may be comprised of a stack gate including a selection gate 30 simultaneously formed with the floating gate 21 of the memory transistor T₁, an insulation pattern 31 simultaneously formed with the inter-gate insulation film 22, and a pseudo gate 32 simultaneously formed with the control gate 23. The selection transistor T₂ may be a single gate of the selection gate 30 simultaneously formed with the float gate 21 of the memory transistor T₁. The selection transistor T₂ includes a source/drain region, N⁺ or N⁻, located in the semiconductor substrate Psub and arranged on two side walls of the selection gate 30. Although it is not shown, the source/drain region may be of a lightly doped drain (LDD) type in an N⁻ impurity region and an N⁺ impurity region or a mask island double diffused drain (DDD) type formed by limiting the N⁺ impurity region in the N⁻ impurity region. However, the source/drain region can be present in a variety of alternative forms.

A gate insulation film 12 is interposed between the pocket P-type well PPwell and the selection gate 30. The gate insulation film 12 may be comprised of a combination of an oxide film and a deposition film.

The high voltage switching device T₃ is located in the deep N-type well DNwell formed in the P-type semiconductor substrate Psub. The high voltage switching device T₃ has a shape encompassing the pocket P-type well PPwell and areas close thereto. The memory cell block includes a plurality of the memory cells comprising the memory transistor T₁ and the selection transistor T₂.

The high voltage switching device T₃ includes a high voltage gate 40 and a source/drain region P⁺ located in the semiconductor substrate Psub and arranged on two side walls of the high voltage gate 40. Although it is not shown, the source/drain region may be of a lightly doped drain (LDD) type in an P⁻ impurity region and an P⁺ impurity region or a mask island double diffused drain (DDD) type formed by limiting the N⁺ impurity region in the N⁻ impurity region. The source/drain region may alternatively have other forms.

The high voltage gate 40 may be comprised of a single layer as shown in FIG. 4 or a dual layer of a first high voltage gate (not shown) simultaneously formed with the floating gate 21 of the memory transistor T₁ and a second high voltage gate (not shown) simultaneously formed with the control gate 23 of the memory transistor T₁. A gate insulation film 13 is interposed between the deep N-type well DNwell and the high voltage gate 40.

Since the high voltage switching device T₃ utilizes a high pressure-resistant feature, the thickness of the gate insulation film 13 of the high voltage switching device T₃ exceeds a predetermined length. A channel region 15 exceeds another predetermined length. Thus, the deep N-type well DNwell under the high voltage gate 40 of the high voltage switching device T₃ is formed in a recess region 18. The lower surface of the high voltage gate 40 is curved along the shape of a recess of the deep N-type well DNwell. The gate insulation film 13 located between the lower surface of the high voltage gate 40 and the deep N-type well DNwell has a curved shape.

The channel region 15 is located in the deep N-type well DNwell under the curved gate insulation film 13. For example, the channel region 15 is defined in the deep N-type well DNwell between the source/drain region P⁺ of the high voltage switching device T₃. The channel region 15 has a 3-D structure having a curve line along the shape of a recess of the deep N-type well DNwell. The recess region 18 is formed deeper than the junction depth of the source/drain region P⁺. The channel region 15 under the high voltage gate 40 can have a curved shape that is shallower than the source/drain region P⁺. Thus, even when the width of the high voltage gate 40 is reduced, by increasing the depth of the recess region 18, the length of a channel of the high voltage switching deice T₃ can be maintained or increased. The gate insulation film 13 having a curved shape formed on the channel region 15 having the above 3-D structure comprises a combination of an oxide film and a deposition film.

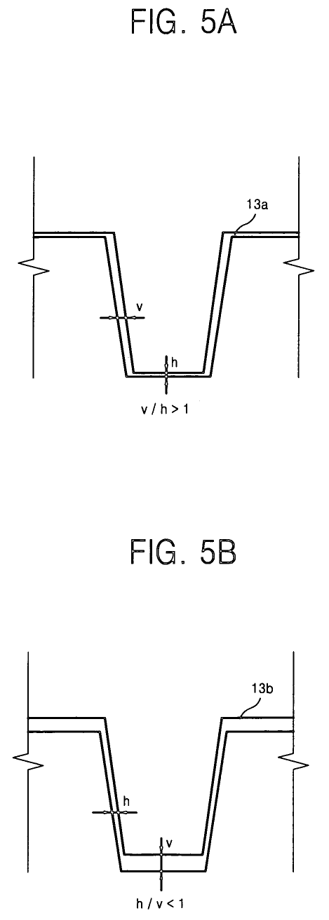

FIGS. 5A and 5B are cross-sectional views showing the gate insulation film located in the upper portion of the recessed channel region of the non-volatile memory device of FIG. 1. As shown in FIGS. 5A and 5B, a ratio in thickness (h/v) of an oxide film 13a and a deposition film 13b exhibits a reverse ratio in the horizontal surface and vertical surface. For example, the thickness ratio (h/v) of the oxide film is greater than 1 while the thickness ratio (h/v) of the deposition film is less than 1.

Thus, the gate insulation film 13 having a curved shape comprises a combination of the oxide film 13a and the deposition film 13b. The gate insulation film 13 formed on the recessed channel region 15 of a 3-D structure has a substantially uniform thickness over the entire upper surface of the horizontal and vertical channels.

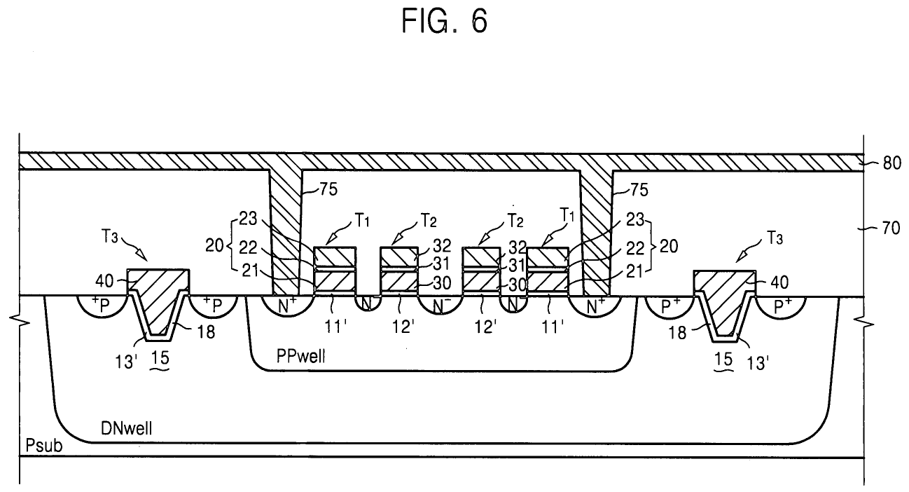

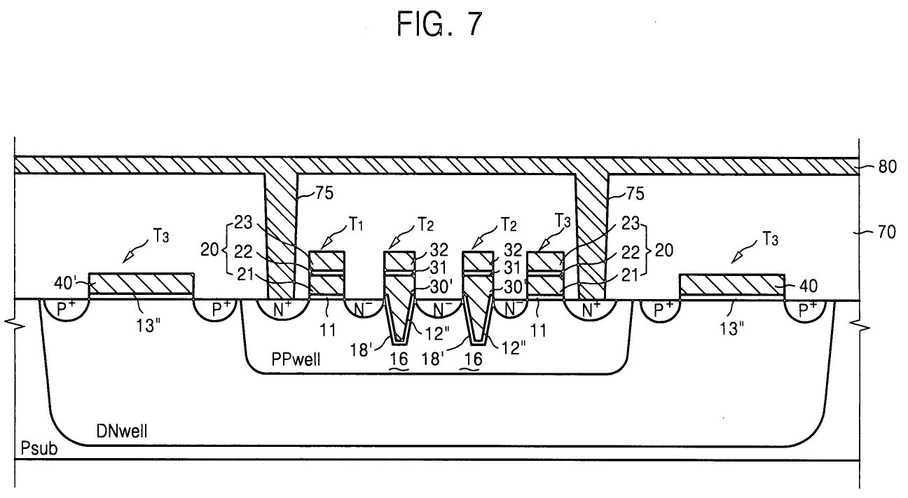

FIG. 6 is a cross-sectional view showing a part of a non-volatile memory device according to another exemplary embodiment of the present invention. Referring to FIG. 6, the non-volatile memory device according to the present embodiment is substantially the same as the no-volatile memory device according to the above-described embodiment except for the difference in thickness between gate insulation films 11′ and 12′ provided in the memory transistor T₁ and the selection transistor T₃ and a gate insulation film 13′ provided in the high voltage switching device T₃.

A tunneling area of the gate insulation film 11′ of the memory transistor T₁ has a thickness capable of allowing for F-N tunneling. The gate insulation film 13′ of the high voltage switching device T₃ has a thickness suitable for a high pressure-resistant feature. Thus, the thickness of the gate insulation films 11′ and 12′ of the memory transistor T₁ and the selection transistor T₂ and the thickness of the gate insulation film 13′ of the high voltage switching device T₃ may be different from each other. For example, the thickness of the gate insulation film 13′ of the high voltage switching device T₃ is greater than that of the gate insulation films 11′ and 12′ of the memory transistor T₁.

Non-volatile memory devices according to other exemplary embodiments of the present invention will be described below with reference to FIGS. 7 through 12. FIGS. 7 through 12 are cross-sectional views showing parts of non-volatile memory devices according to other exemplary embodiments of the present invention.

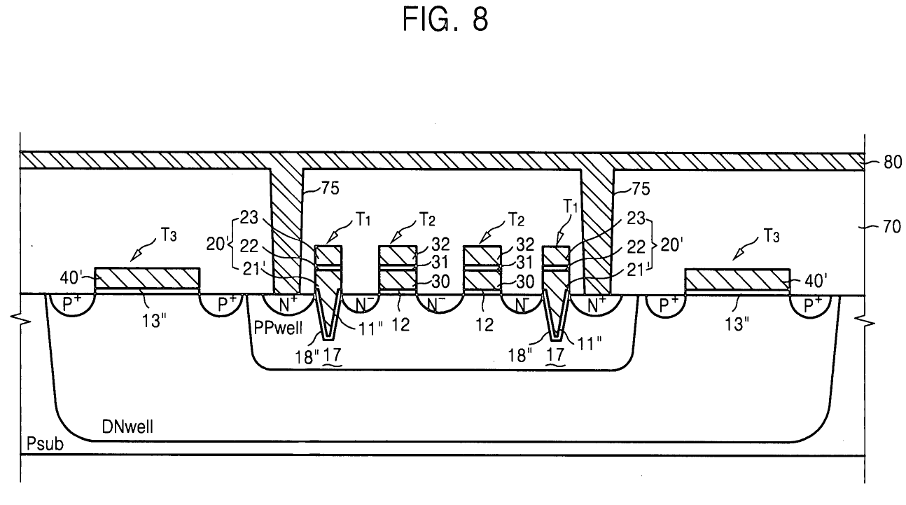

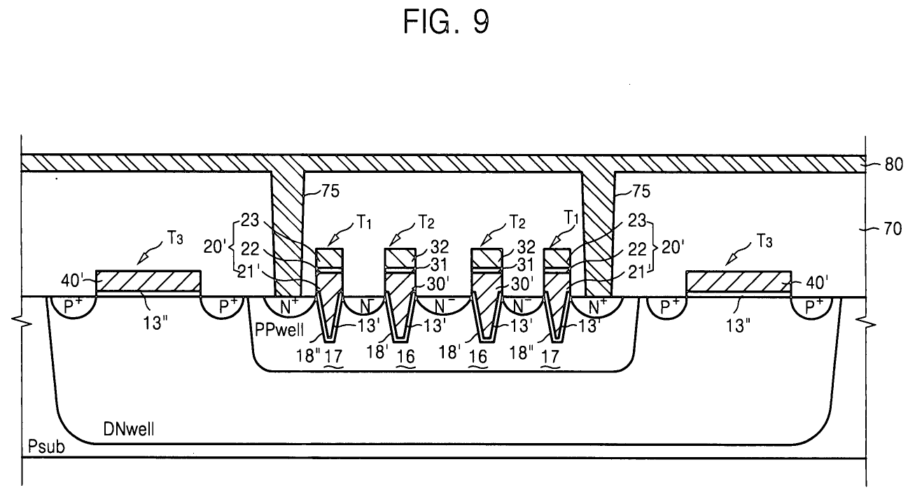

As shown in FIGS. 7 through 9, the non-volatile memory devices are substantially the same as the non-volatile memory devices according to the above-described embodiment shown in FIGS. 1 through 6, in which the recessed channel region 15 of FIG. 4 is located under the high voltage gate 40 of FIG. 4. However in the embodiment shown in FIGS. 7 though 9, a recessed channel region 16 is located under the selection gate 30′ of the selection transistor T₂ (FIG. 7), a recessed channel region 17 is located under the memory gate 20′ having the floating gate 21′ of the memory transistor T₁ (FIG. 8), and recessed channel regions 16 and 17 are simultaneously located under the memory gate 20′ of the memory transistor T₁ and the selection gate 30′ of the selection transistor T₂ (FIG. 9). The width of the high voltage gate 40′ of the high voltage switching device T₃ is greater than the width of the high voltage gate 40 of FIG. 4 to be suitable for the high pressure-resistant feature.

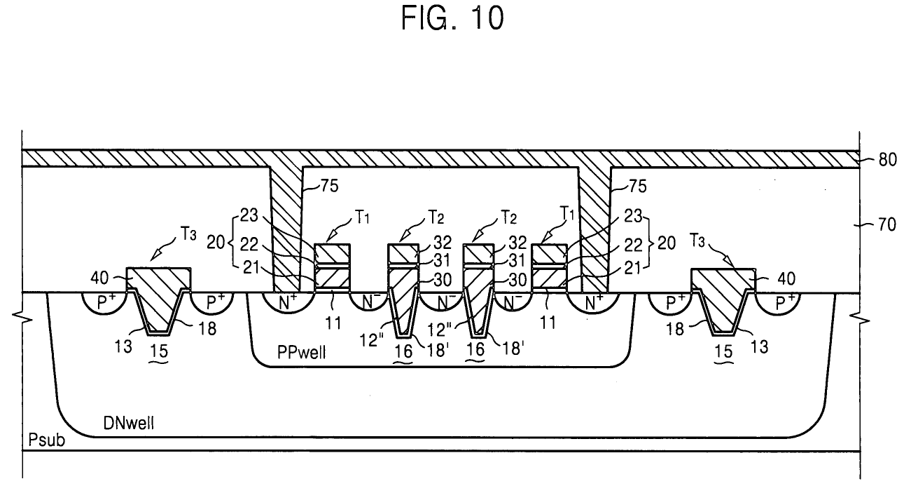

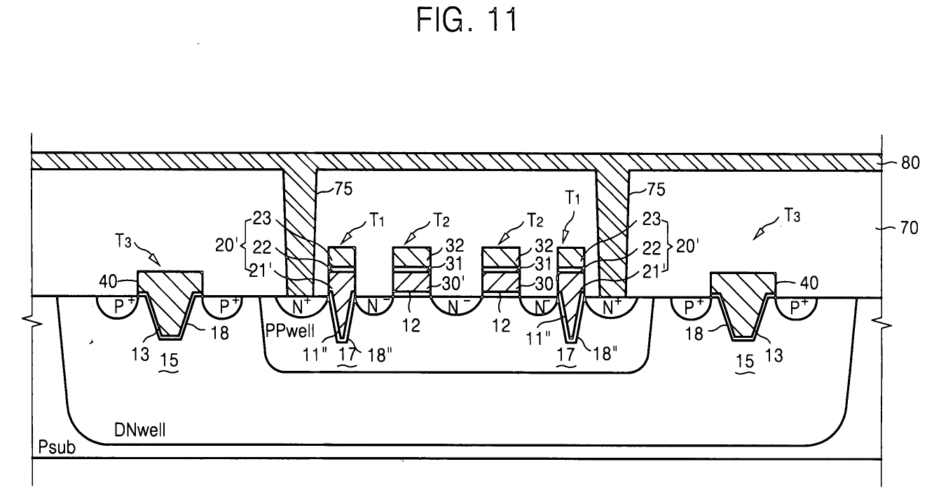

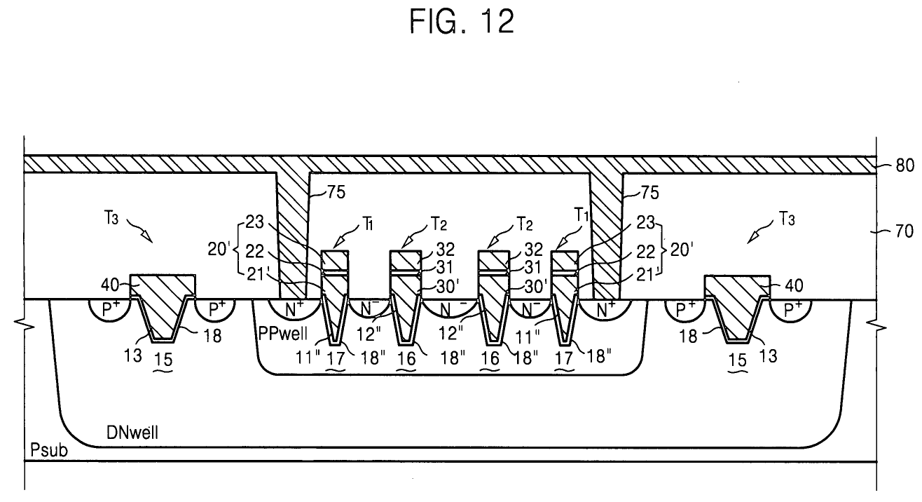

As shown in FIGS. 10 through 12, non-volatile memory devices according to exemplary embodiments of the present invention are substantially the same as the non-volatile memory device according to the above-described embodiment of FIGS. 7 through 9, except that the recessed channel region 16 is located under the selection gate 30′ of the selection transistor T₂ (FIG. 10), the recessed channel region 17 is located under the memory gate 20′ having the float gate 21′ of the memory transistor T₁ (FIG. 11), and the recessed channel regions 16 and 17 are simultaneously located under the memory gate 20′ of the memory transistor T₁ and the selection gate 30′ of the selection transistor T₂ (FIG. 12), at the same time, the recessed channel region 15 is located under the high voltage gate 40 of the high voltage switching device T₃.

In FIGS. 7 through 12, the non-volatile memory device includes gate insulation films 11″, 12″, and 13 of the memory transistor T₁, the selection transistor T₂, and the high voltage switching device T₃, respectively, and recess regions 18′ and 18″.

The gate insulation films 11, 12, and 13 provided in the memory transistor T₁, the selection transistor T₂, and the high voltage switching device T₃, respectively, may be formed of a combination of an oxide film and a deposition film. In this case, even for the gate insulation film 13 having a curved shape, the horizontal thickness and the vertical thickness may be substantially uniform.

Also, although it is not shown in the non-volatile memory devices, according to the above-described embodiments, the gate insulation films provided in the memory transistor T₁, the selection transistor T₂, and the high voltage switching device T₃ may have different thicknesses. For example, the thickness of the gate insulation film of the high voltage switching device T₃ is greater than that of the gate insulation films of the memory transistor T₁ and the selection transistor T₂.

As described above, since the non-volatile memory devices according to the above-described embodiments include the recessed channel regions, embodiments of the present invention may be pressure-resistant, punch-through of the transistor are secured, and a small occupancy area is provided to facilitate chip scaling. Also, by making diverse gate insulation films according to the purpose of each device, the performance of the transistor is optimized so that the performance and leakage characteristic of the overall chip can be enhanced.

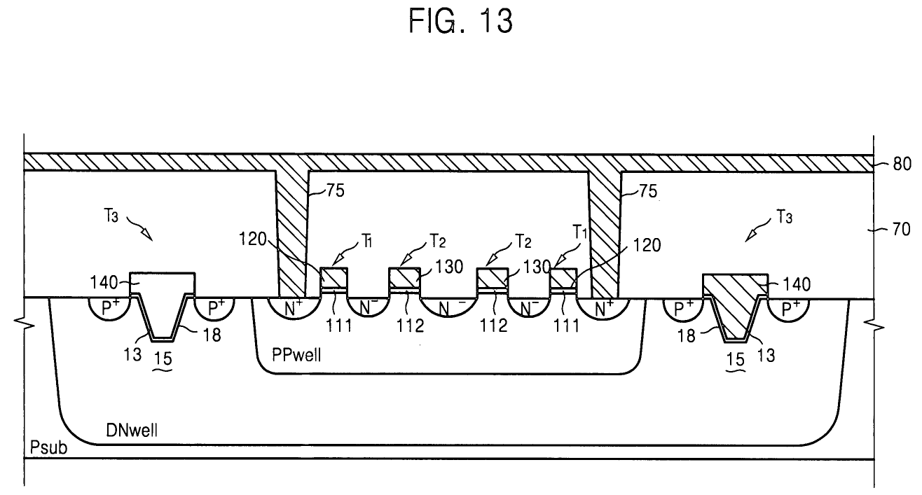

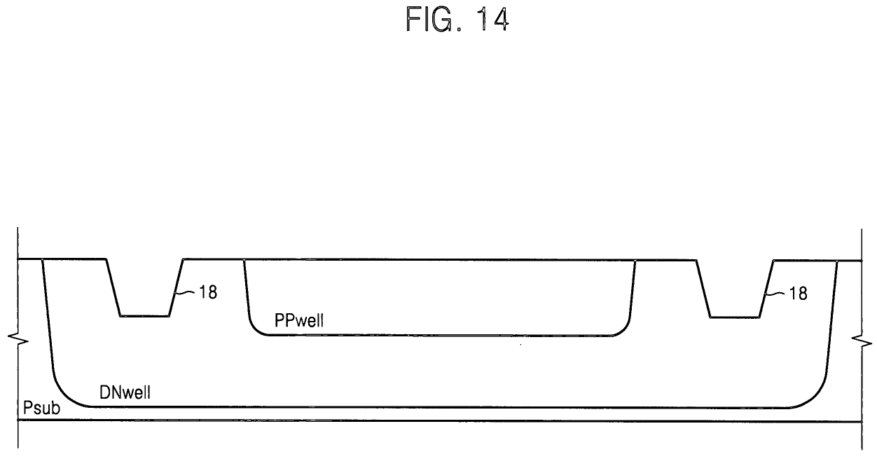

Next, a non-volatile memory device according to an exemplary embodiment of the present invention will be described below with reference to FIG. 13. FIG. 13 is a cross-sectional view showing part of a non-volatile memory device according to an exemplary embodiment of the present invention. The non-volatile memory device is substantially the same as the non-volatile memory devices according to the above-described embodiment, except for a single gate structure unlike the non-volatile memory devices according to the above-described embodiment in which the memory transistor has a stack gate structure. Thus, the non-volatile memory device according to this exemplary embodiment of the present invention will be described based on the memory cell region that is different from that of the non-volatile memory devices according to the above-described embodiment.

As shown in FIG. 13, a memory cell of the non-volatile memory device according to the present exemplary embodiment includes the memory transistor T₁ and the selection transistor T₂. The memory transistor T₁ includes a memory gate 120 and the source/drain region N⁺ or N⁻ located in the semiconductor substrate Psub and arranged on both side walls of the memory gate 120. The memory gate 120 can include, for example, doped polysilicon. Although it is not shown, the source/drain region may be of a lightly doped drain (LDD) type in an N⁻ impurity region and an N⁺impurity region or a mask island double diffused drain (DDD) type formed by limiting the N⁺ impurity region in the N⁻ impurity region. However, the present invention is not limited to the above types so that the source/drain region can be present in a variety of forms.

An electric charge storage insulation film 111 is interposed between the pocket P-type well PPwell and the memory gate 120. The electric charge storage insulation film 111 can be formed of a tunnel insulation layer, an electric charge trap layer, and a blocking insulation layer which are sequentially deposited. For example, the electric charge storage insulation film 111 can be formed of a stack layer of a silicon oxide film SiOx, a silicon nitride film SiNx, and a silicon oxide film SiOx, a stack layer of a silicon oxide film SiOx, a silicon nitride film SiNx, and an aluminum oxide film AlOx, a stack layer of a silicon oxide film SiOx, a silicon nitride film SiNx, and a hafnium oxide film HfOx, or a stack layer of a silicon oxide film SiOx, a hafnium oxide film HfOx, a silicon nitride film SiNx, and an aluminum oxide film AlOx.

The selection transistor T₂ serially connected to the memory transistor T₁ is located in the pocket P-type well PPwell. The selection transistor T₂ includes a selection gate 130 that is simultaneously formed with the memory gate 120 of the memory transistor T₁ and the source/drain region N⁺ or N⁻ located in the semiconductor substrate Psub and arranged on both side walls of the selection gate 130. Although it is not shown, the source/drain region may be of a lightly doped drain (LDD) type in an N⁻ impurity region and an N⁺ impurity region or a mask island double diffused drain (DDD) type formed by limiting the N⁺ impurity region in the N⁻ impurity region. However, the present invention is not limited to the above types so that the source/drain region can be present in a variety of forms. Also, a gate insulation film 112 that is simultaneously formed with the electric charge storing insulation film 111 of the memory transistor T1 is interposed between the pocket P-type well PPwell and the selection gate 130.

In the present exemplary embodiment the recessed channel region 15 is included in the high voltage switching device T₃ while the memory transistor T₁ has a single gate structure. The memory transistor T₁ having a single gate structure may also have at least one of the memory transistor T₁, the selection transistor T₂, and the high voltage switching device T₃ includes the recessed channel region.

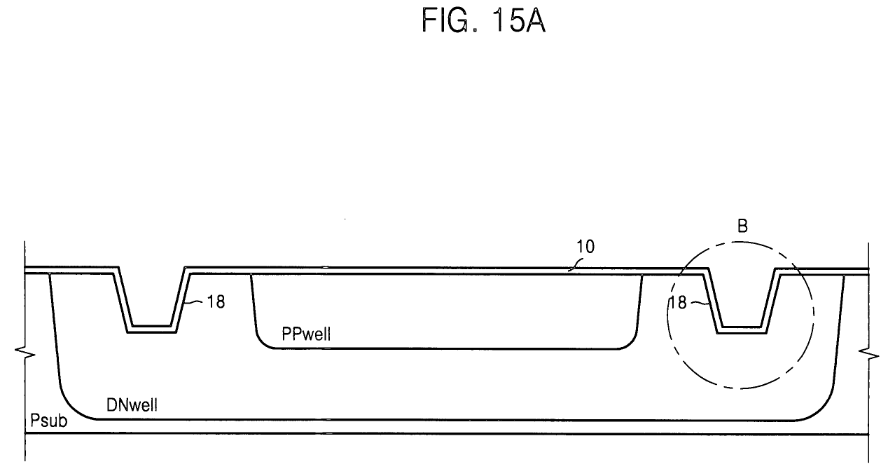

A method for fabricating a non-volatile memory device according to an exemplary embodiment of the present invention will be described with reference to FIGS. 4 and 14 through 16. FIGS. 14 through 16 are cross-sectional views of the intermediate structures which are sequentially arranged in the process order according to a method for fabricating a non-volatile memory device according to an exemplary embodiment of the present invention.

Although in the present exemplary embodiment the P-type semiconductor substrate Psub having the pocket P-type well PPwell and the deep N-type well DNwell encompassing the pocket P-type well PPwell close thereto is mainly described, the present invention is not limited thereto.

As shown in FIG. 14, the P-type semiconductor substrate Psub having the pocket P-type well PPwell and the deep N-type well DNwell encompassing the pocket P-type well PPwell close thereto is provided. The pocket P-type well PPwell corresponds to a memory cell block forming area and the deep N-type well DNwell corresponds to the formation area of the high voltage switching device T₃ controlling the memory cell in units of bytes.

A hard mask pattern (not shown) to expose a predetermined part of the deep N-type well DNwell is formed on the semiconductor substrate Psub. Next, the recess region 18 is formed by etching the deep N-type well DNwell exposed by the hard mask pattern by using the hard mask pattern as an etching mask. Then, the hard mask pattern is removed.

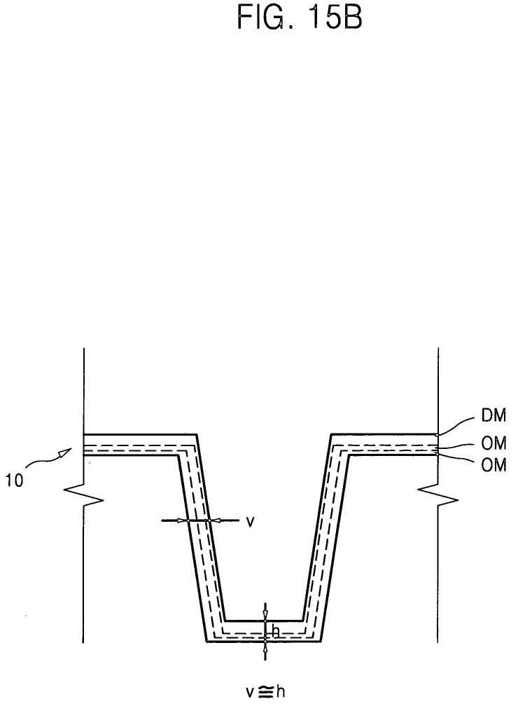

Next, as shown in FIG. 15A, a gate insulation film 10 is formed on the entire surface of the semiconductor substrate Psub. The gate insulation film 10 is formed by combining an oxidation method OM and a deposition method DM to have a uniform thickness on the horizontal surface and the vertical surface of the recess region 18 that is curved.

Referring to FIG. 15B that is an enlarged view of a B area of FIG. 15A, the gate insulation film 10 having a desired thickness can be obtained by repeatedly performing the oxidation method OM to make the gate insulation film 10 relatively thicker on the vertical surface than on the horizontal surface and the deposition method DM to make the gate insulation film 10 relatively thicker on the horizontal surface than on the vertical surface. The oxidation method OM forming the gate insulation film 10 includes, for example, a thermal oxidation method. The deposition method includes, for example, a chemical vapor deposition method. However, the present invention is not limited thereto and a variety of oxidation methods and deposition methods can be used for forming the gate insulation film. Also, the order and number of use of the oxidation method and the deposition method may vary according to the desired thickness of the gate insulation film 10. Further, the gate insulation film 10 having various thicknesses according to the characteristic of a device can be embodied using a mask (not shown).

In addition, before or after the formation of the gate insulation film 10, the gate insulation film 10 is cleaned or the step coverage ratio of the gate insulation film 10 can be changed using a dry or wet process. As described above, when the gate insulation film 10 is formed by combining the oxidation method and the deposition method, the gate insulation film 10 formed above the recess region 18 that is curved can have a substantially uniform thickness throughout the entire area.

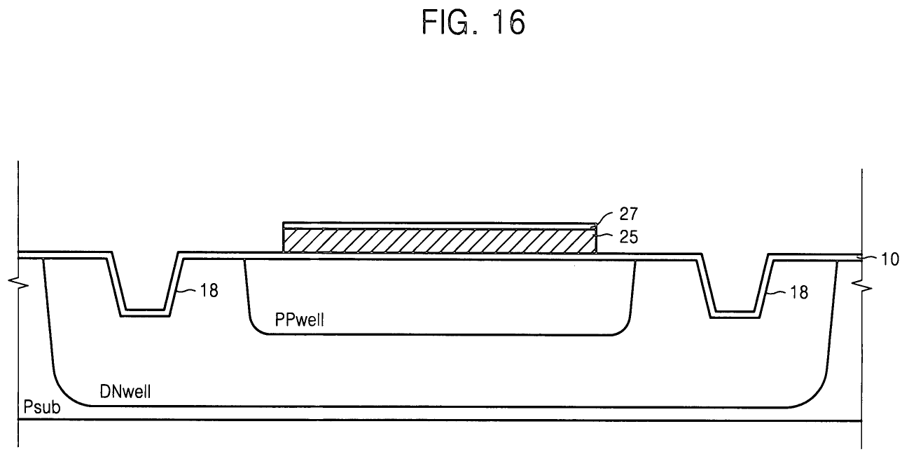

Next, as shown in FIG. 16, a lower conductive film 25 is formed on the entire surface of the gate insulation film 10. An inter-gate insulation film 27 is formed on the lower conductive film 25 and patterned to remove the inter-gate insulation film 27 and the lower conductive film 25 above the recess region 18.

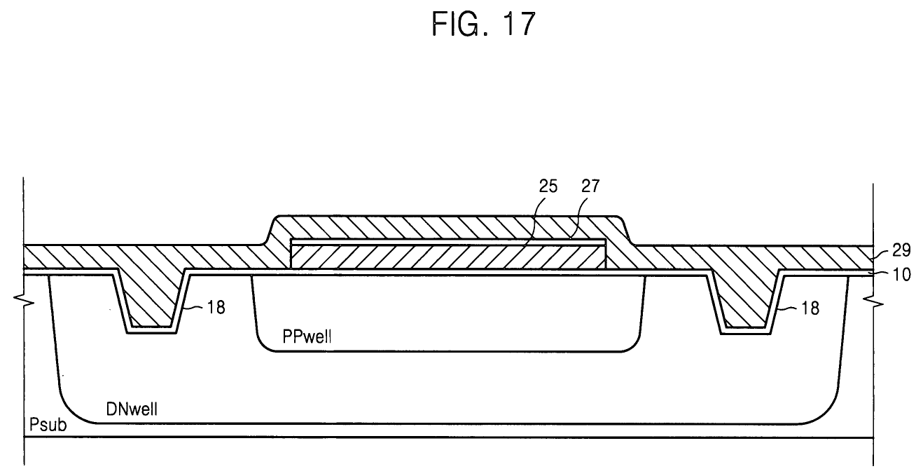

As shown in FIG. 17, an upper conductive film 29 is formed. Next, as shown in FIG. 4, the gate insulation film 13 and the high voltage gate 40 are formed by patterning the gate insulation film 10 and the upper conductive film 29 formed above the recess region 18. Also, by patterning the gate insulation film 10, the lower conductive film 25, the inter-gate insulation film 27, and the upper conductive film 29 which are formed on and above the pocket P-type well PPwell, the gate insulation film 11 and the memory gate 20 having the float gate 21, the inter-gate insulation film 22, and the control gate 23, and the gate insulation film 12 and the gate of the selection transistor T₂ having the selection gate 30, the insulation film pattern 31, and the pseudo gate 32.

Next, the source/drain regions N⁺, N⁻, or P⁺ are formed by injecting impurity ions of N⁺, N⁻, or P⁺ using each gate formed on the semiconductor substrate Psub as an ion injection mask, to complete the memory transistor T₁, the selection transistor T₂, and the high voltage switching device T₃. The recessed channel region 15 is defined in the deep N-type well DNwell between the source/drain region P⁺ of the high voltage switching device T₃.

The interlayer insulation film 70 is formed on the entire surface of the semiconductor substrate Psub where the memory transistor T₁, the selection transistor T₂, and the high voltage switching device T₃ are formed. Then, after the contact hole 75 exposing the drain region N⁺ of the memory transistor T₁ is formed, the bit line 80 electrically connecting to the drain region N⁺ of the memory transistor T₁ through the contact hole 75 is formed. Thereafter, the non-volatile memory device is completed in a typical method for fabricating a non-volatile memory device.

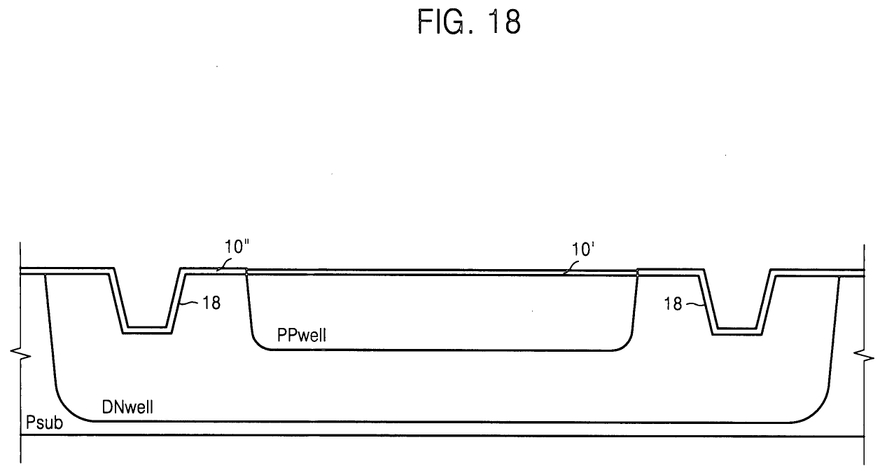

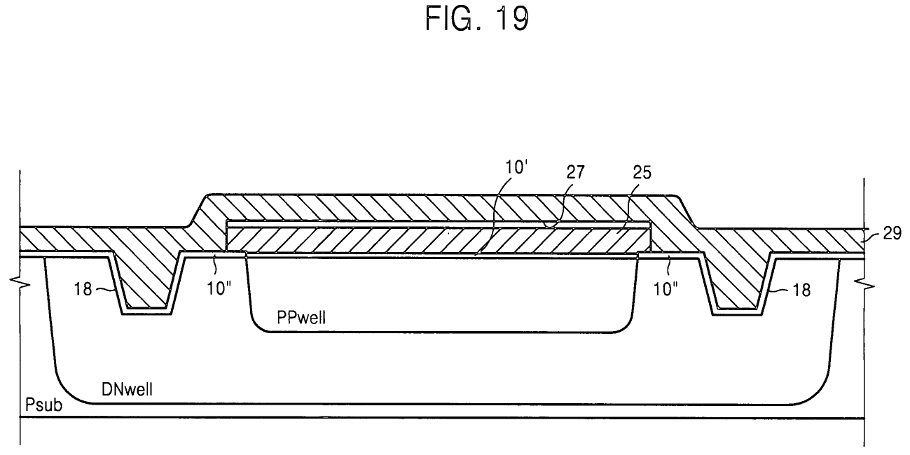

A method for fabricating a non-volatile memory device according to an exemplary embodiment of the present invention will be described with reference to FIGS. 6, 14, 18, and 19. FIGS. 18 and 19 are cross-sectional views of the intermediate structures which are sequentially arranged in the process order according to a method for fabricating a non-volatile memory device according to the exemplary embodiment of the present invention.

As shown in FIG. 14, the recess region 18 is formed in the deep N-type well DNwell of the semiconductor substrate Psub that is substantially the same as the semiconductor substrate Psub used in the above-described method for fabricating a non-volatile memory device. Next, as shown in FIG. 18, a first gate insulation film 10′ is formed on the entire surface of the semiconductor substrate Psub. The first gate insulation film 10′ can be formed, for example, in a chemical vapor deposition method, a low pressure chemical vapor deposition method, or a plasma chemical vapor deposition method. However, the present invention is not limited thereto.

The first gate insulation film 10′ is partially removed by covering a part of the semiconductor substrate Psub corresponding to the pocket P-type well PPwell where the memory transistor T₁ and the selection transistor T₂ are formed. Part of the semiconductor substrate Psub corresponding to the deep N-type well DNwell where the recess region 18 is formed is exposed.

A second gate insulation film 10 that is relatively thicker than the first gate insulation film 10′ is formed on the semiconductor substrate Psub. The first gate insulation film 10′ is partially removed. The second gate insulation film 10″ having a desired thickness can be formed by combining the oxidation method and the deposition method to allow the second gate insulation film 10″ to be formed to a uniform thickness on the horizontal and vertical surfaces of the recess region 18 that is curved. The oxidation method for forming the second gate insulation film 10″ includes, for example, a thermal oxidation method, and the deposition method includes, for example, a chemical vapor deposition method. However, the present invention is not limited to the above methods and the gate insulation film can be formed using a variety of oxidation methods and deposition methods. Also, the repetition order and number of use of the oxidation method and the deposition method may vary according to the desired thickness of the second gate insulation film 10″. Furthermore, the second gate insulation film 10″ having various thicknesses according to the characteristic of a device can be embodied using a mask (not shown). In addition, before or after the formation of the second gate insulation film 10″, the second gate insulation film 10″ is cleaned and/or the step coverage ratio of the second gate insulation film 10″ can be changed using a dry or wet process. As described above, when the second gate insulation film 10″ is formed by combining the oxidation method and the deposition method, the second gate insulation film 10″ formed above the recess region 18 that is curved can have a substantially uniform thickness throughout the entire area.

Although in the present embodiment the second gate insulation film 10″ is formed after the first gate insulation film 10′ is formed, the order of forming of the first gate insulation film 10′ and the second gate insulation film 10″ is not limited thereto.

As shown in FIG. 19, the lower conductive film 25 is formed on the entire surfaces of the first gate insulation film 10′ and the second gate insulation film 10″. The inter-gate insulation film 27 is formed on the lower conductive film 25 and the inter-gate insulation film 27 and the lower conductive film 25 above the recess region 18 is removed by patterning the inter-gate insulation 27 and the lower conductive film 25. Then, the upper conductive film 29 is formed thereon.

As shown in FIG. 6, the gate insulation film 13′ and the high voltage gate 40 are formed by patterning the second gate insulation film 10″ and the upper conductive film 29 formed on and above the recess region 18. The gate insulation film 11′, the memory gate 20 having the float gate 21, the inter-gate insulation film 22, and the control gate 23 may be formed. The gate insulation film 12′, the gate of the selection transistor T₂ having the selection gate 30, the insulation film pattern 31, and the pseudo gate 32 may be formed by patterning the first gate insulation film 10′, the lower conductive film 25, the inter-gate insulation film 27, and the upper conductive film 29.

Next, the source/drain regions N⁺, N⁻, or P⁺ are formed by injecting impurity ions of N⁺, N⁻, or P⁺ using each gate formed on the semiconductor substrate Psub as an ion injection mask, to thus complete the memory transistor T₁, the selection transistor T₂, and the high voltage switching device T₃. The recessed channel region 15 is defined in the deep N-type well DNwell between the source/drain region P⁺ of the high voltage switching device T₃.

The interlayer insulation film 70 is formed on the entire surface of the semiconductor substrate Psub where the memory transistor T₁, the selection transistor T₂, and the high voltage switching device T₃ are formed. Then, after the contact hole 75 exposing the drain region N⁺ of the memory transistor T₁ is formed, the bit line 80 electrically connecting to the drain region N⁺ of the memory transistor T₁ through the contact hole 75 is formed. Thereafter, the non-volatile memory device is completed in a typical method for fabricating a non-volatile memory device.

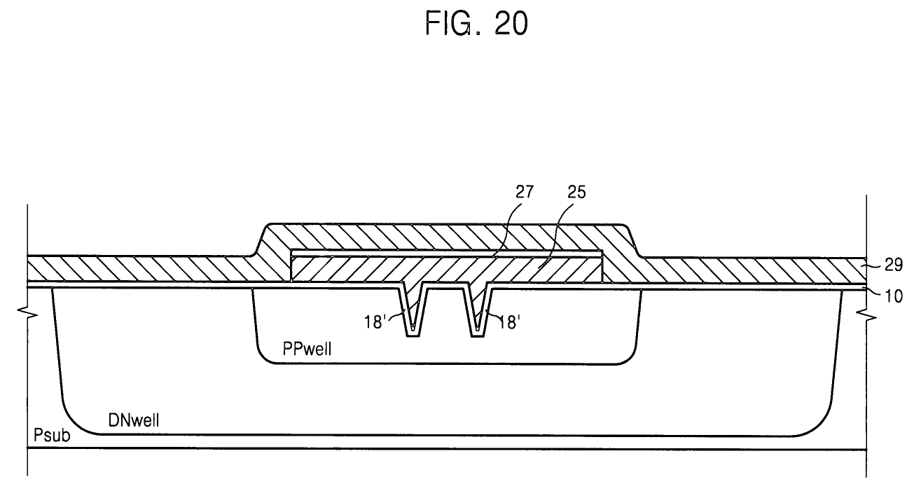

Next, a method for fabricating a non-volatile memory device according to yet another embodiment of the present invention will be described with reference to FIGS. 7 through 14 and 20 through 25. FIGS. 20 through 25 are cross-sectional views of the intermediate structures which are sequentially arranged in the process order according to a method for fabricating a non-volatile memory device according to an exemplary embodiment of the present invention.

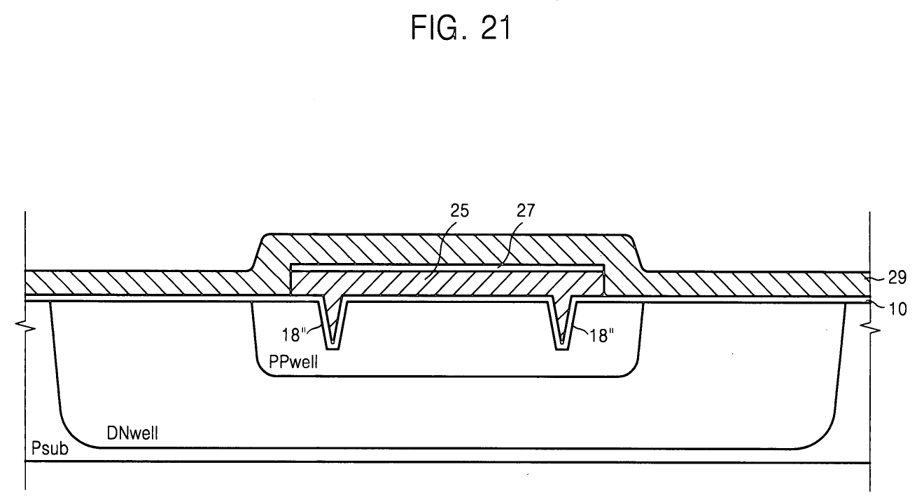

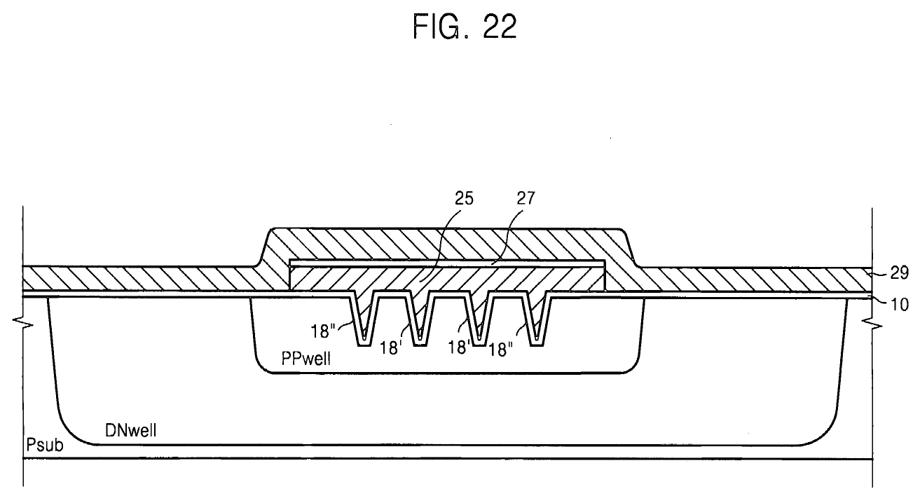

As shown in FIGS. 20 through 22, the non-volatile memory device according to the above-described embodiment as shown in FIGS. 7 through 9 can be manufactured in the method of the present embodiment, except that the recess region 18‘is’ formed in the area where the selection transistor T₂ in the pocket P-type well PPwell is formed (FIG. 20). The recess region 18″ is formed in the region where the memory transistor T₁ is formed (FIG. 21). The recess regions 18′ and 18″ may be simultaneously formed in the area where the selection transistor T₂ and the memory transistor T₁ are formed (FIG. 22), instead of forming the recess region 18 in the deep N-type well DNwell of the semiconductor substrate Psub. The high voltage gate 40′ of the high voltage switching device T₃ is formed to be greater than the width of the high voltage gate 40 of FIG. 4 in the non-volatile memory device according to the above-described embodiment of the present invention to be suitable for the high pressure-resistant characteristic.

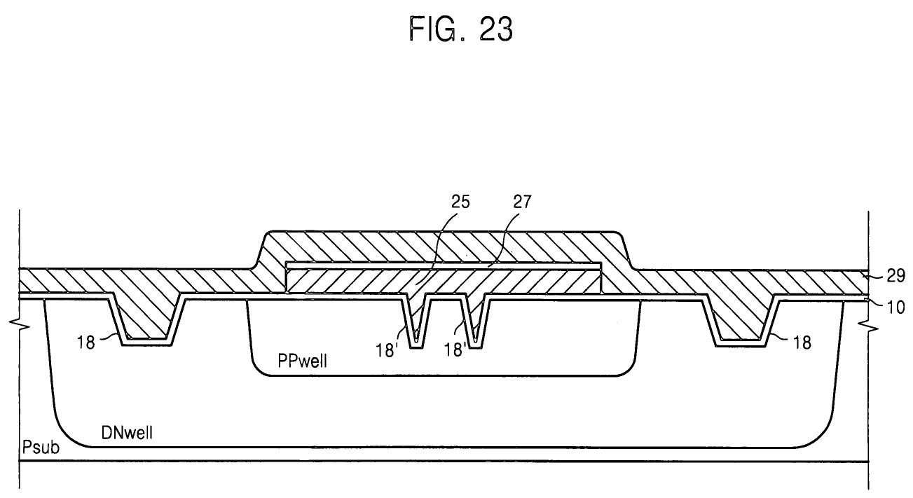

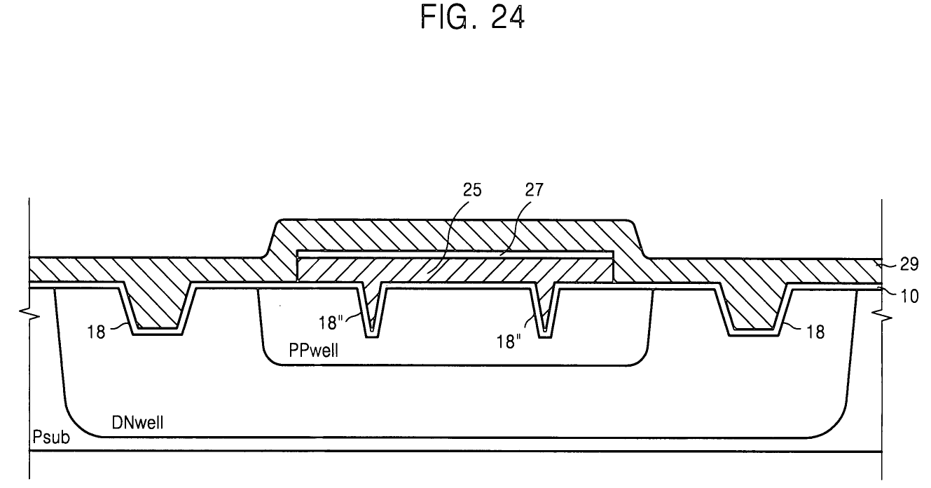

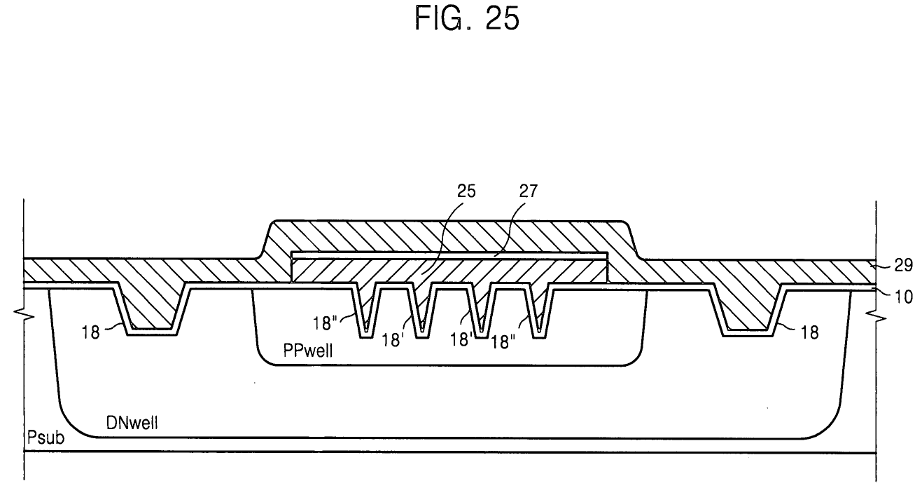

As shown in FIGS. 23 through 25, the non-volatile memory device according to the above-described embodiment as shown in FIGS. 10 through 12 can be manufactured in the method of the present embodiment, except that the recess region 18′ is formed in the area where the selection transistor T₂ in the pocket P-type well PPwell is formed (FIG. 23). The recess region 18″ is formed in the region where the memory transistor T₁ is formed (FIG. 24). The recess regions 18′ and 18″ may be simultaneously formed in the area where the selection transistor T₂ and the memory transistor T₁ are formed (FIG. 25) at the same time as the recess region 18′ is formed in the deep N-type well DNwell of the semiconductor substrate Psub.

Although it is not shown, the thicknesses of the gate insulation film of the memory transistor T₁, the selection transistor T₂, and the gate insulation film of the high voltage switching device T₃ may be formed as in the method for fabricating a non-volatile memory device according to the above-described another embodiment the present invention.

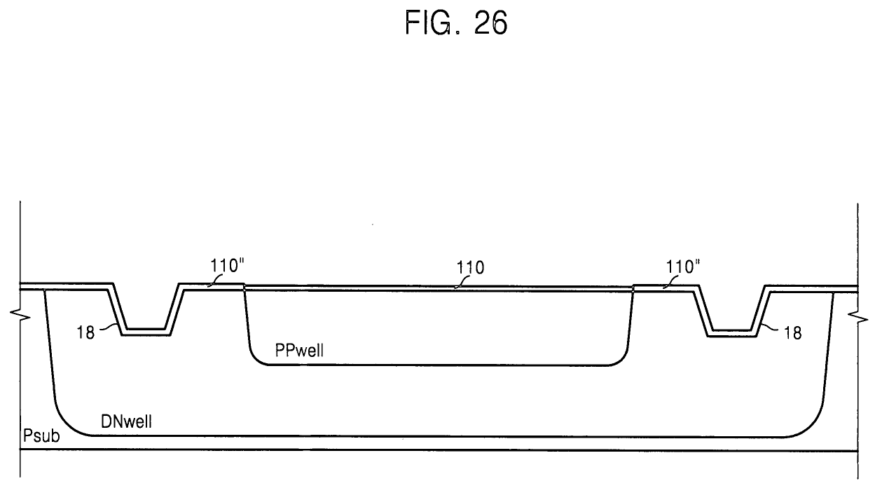

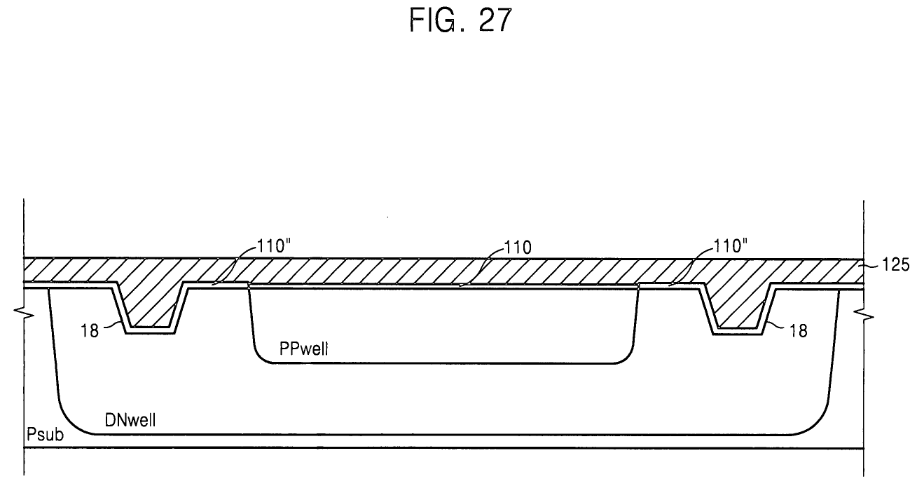

The method for fabricating a non-volatile memory device according to yet another embodiment of the present invention will be described with reference to FIGS. 13, 14, 26, and 27. FIGS. 26 and 27 are cross-sectional views of the intermediate structures which are sequentially arranged in the process order according to the method for fabricating a non-volatile memory device according to yet another embodiment of the present invention.

As shown in FIG. 14, the recess region 18 is formed in the deep N-type well DNwell of the semiconductor substrate Psub that is substantially the same as the semiconductor substrate Psub used in the method for fabricating a non-memory device according to the above-described embodiment of the present invention.

Next, as shown in FIG. 26, the electric charge storage insulation film 110, where the tunnel insulation layer, the electric charge trap layer, and the blocking insulation layer are deposited, is formed on the entire surface of the semiconductor substrate Psub. The electric charge storage insulation film 110 can be formed of a stack layer of a silicon oxide film SiOx, a silicon nitride film SiNx, and a silicon oxide film SiOx. The electric charge storage insulation film 110 can also be formed on a stack layer of a silicon oxide film SiOx, a silicon nitride film SiNx, and an aluminum oxide film AlOx. The electric charge storage insulation film 110 can also be formed on a stack layer of a silicon oxide film SiOx, a silicon nitride film SiNx, and a hafnium oxide film HfOx. The electric charge storage insulation film 110 can also be formed on a stack layer of a silicon oxide film SiOx, a hafnium oxide film HfOx, a silicon nitride film SiNx, and an aluminum oxide film AlOx.

The electric charge storage insulation film 110 is removed by covering the semiconductor substrate Psub corresponding to the pocket P-type well PPwell where the memory transistor T₁ and the selection transistor T₂ are formed and exposing the semiconductor substrate Psub corresponding to the deep N-type well DNwell where the recess region 18 is formed.

Next, the gate insulation film 110″ is formed on the semiconductor substrate Psub where the electric charge storage insulation film 10 is partially removed. The gate insulation film 110″, having a desired thickness, can be formed by combining the oxidation method and the deposition method to allow the gate insulation film 110″ to be formed to a uniform thickness on the horizontal and vertical surfaces of the recess region 18 that is curved. The oxidation method forming the gate insulation film 110″ includes, for example, a thermal oxidation method. The deposition method includes, for example, a chemical vapor deposition method. However, the present invention is not limited thereto and a variety of oxidation methods and deposition methods can be used for forming the gate insulation film. Also, the order and number of use of the oxidation method and the deposition method may vary according to the desired thickness of the gate insulation film 110″. Further, the gate insulation film 110″ having various thicknesses according to the characteristic of a device can be embodied using a mask (not shown).

In addition, before or after the formation of the gate insulation film 110″, the gate insulation film 110″ is cleaned and/or the step coverage ratio of the gate insulation film 110″ can be changed using a dry or wet process. As described above, when the gate insulation film 110″ is formed by combining the oxidation method and the deposition method, the gate insulation film 110″ formed above the recess region 18 that is curved can have a substantially uniform thickness throughout the entire area.

Although in the present embodiment the gate insulation film 110″ is formed after the electric charge storage insulation film 10 is formed, the order of formation of the electric charge storage insulation film 110 and the gate insulation film 110″ is not limited thereto.

Next, as shown in FIG. 27, a conductive film 125 is formed on the entire surface of the electric charge storage insulation film 110 and the gate insulation film 110″. Next, as shown in FIG. 13, the gate insulation film 13 and the high voltage gate 140 are formed by patterning the gate insulation film 110″ and the conductive film 125 formed above the recess region 18. Also, by patterning the electric charge storage insulation film 110″ and the conductive film 125 formed on the pocket P-type well PPwell, the gate of the memory transistor T₁ having the electric charge storage insulation film 111 and the memory gate 120 and the gate of the selection transistor T₂ having the gate insulation film 112 and the selection gate 130.

Next, the source/drain regions N⁺, N⁻, or P⁺ are formed by injecting impurity ions of N⁺, N⁻, or P⁺ using each gate formed on the semiconductor substrate Psub as an ion injection mask. This completes the memory transistor T₁, the selection transistor T₂, and the high voltage switching device T₃. The recessed channel region 15 is defined in the deep N-type well DNwell between the source/drain region P⁺ of the high voltage switching device T₃.

The interlayer insulation film 70 is formed on the entire surface of the semiconductor substrate Psub where the memory transistor T₁, the selection transistor T₂, and the high voltage switching device T₃ are formed. After the contact hole 75 exposing the drain region N⁺ of the memory transistor T₁ is formed, the bit line 80 electrically connecting to the drain region N⁺ of the memory transistor T₁ through the contact hole 75 is formed. Thereafter, the non-volatile memory device is completed in a typical method for fabricating a non-volatile memory device.

In the present embodiment, the method for fabricating a non-volatile memory device in which the recessed channel region 15 is included in the high voltage switching device T₃ while the memory transistor T₁ has a single gate structure is described. However, the present invention can also be applied to a method for fabricating a non-volatile memory device in which the memory transistor T₁ has a single gate structure and at least one of the memory transistor T₁, the selection transistor T₂, and the high voltage switching device T₃ includes the recessed channel region.

As described above, the non-volatile memory devices fabricated in the method according to the described exemplary embodiments of the present invention include the recessed channel region. Accordingly, the characteristics of pressure-resistant and punch-through of the transistor are secured and a small occupancy area is provided. These features may facilitate chip scaling. Also, by making diverse gate insulation films according to the purpose of each device, the performance of the transistor is optimized so that the performance and leakage characteristic of the overall chip can be enhanced.

While the above-described exemplary embodiments have been particularly shown and described with reference to the figures, it will be understood by those skilled in the art that various changes in form and details may be made therein without departing from the spirit and scope of the disclosure as.

Since the recessed channel region is included and the gate insulation film having a uniform thickness is formed above the recessed channel region, the occupancy area can be reduced and further a non-volatile memory device having a superior device characteristic can be provided.

What is claimed is:

1. A non-volatile memory device comprising:
a memory cell located in a first conductive region and having a memory transistor and a selection transistor; and
a high voltage switching device located in a second conductive region close to the first conductive region and controlling the memory cell,
wherein at least one of the high voltage switching device, the memory transistor, or the selection transistor has a recessed channel region.

2. The non-volatile memory device of claim 1, wherein each of the high voltage switching device, the memory transistor, and the selection transistor comprises a source/drain region and the recessed channel region is recessed deeper than a junction depth of the source/drain region.

3. The non-volatile memory device of claim 1, wherein a gate insulation film formed above the recessed channel region is comprised of an oxidation film and a deposition film.

4. The non-volatile memory device of claim 3, wherein the gate insulation film formed above the recessed channel region has a substantially uniform thickness.

5. The non-volatile memory device of claim 1, wherein the memory transistor comprises a gate insulation film, a float gate, an inter-gate insulation film and a control gate.

6. The non-volatile memory device of claim 1, wherein the memory transistor comprises an electric charge storage insulation film and a gate.

7. The non-volatile memory device of claim 1, wherein the first and second conductive regions are each a well or a semiconductor substrate.

8. The non-volatile memory device of claim 1, wherein the high voltage switching device is a PMOS (p-channel metal-oxide-semiconductor), an NMOS (n-channel metal-oxide-semiconductor), or a CMOS (complementary metal-oxide-semiconductor) transistor.

9. A non-volatile memory device comprising:
a cell block having a plurality of memory cells arranged in units of bytes located in a first conductive well located in a first conductive substrate, each memory cell having a memory transistor and a selection transistor; and
a high voltage switching device located in a second conductive well close to the first conductive well and controlling the memory cells,
wherein at least one of the high voltage switching device, the memory transistor, or the selection transistor has a recessed channel region.

10. The non-volatile memory device of claim 9, wherein each of the high voltage switching device, the memory transistor, and the selection transistor comprises a source/drain region and the recessed channel region is recessed deeper than a junction depth of the source/drain region.

11. The non-volatile memory device of claim 9, wherein a gate insulation film formed above the recessed channel region is comprised of an oxidation film and a deposition film.

12. The non-volatile memory device of claim 11, wherein the gate insulation film formed above the recessed channel region has a substantially uniform thickness.

13. The non-volatile memory device of claim 9, wherein the memory transistor comprises a gate insulation film, a float gate, an inter-gate insulation film and a control gate.

14. The non-volatile memory device of claim 9, wherein the memory transistor comprises an electric charge storage insulation film and a gate.

15. The non-volatile memory device of claim 9, wherein the high voltage switching device is a PMOS (p-channel metal-oxide-semiconductor), an NMOS (n-channel metal-oxide-semiconductor), or a CMOS (complementary metal-oxide-semiconductor) transistor.

16. A method for fabricating a non-volatile memory device, the method comprising:
forming a memory cell having a memory transistor and a selection transistor in a first conductive region; and
forming a high voltage switching device controlling the memory cell in a second conductive region close to the first conductive region,
wherein at least one of the high voltage switching device, the memory transistor, and the selection transistor has a recessed channel region.

17. The method of claim 16, wherein a gate insulation film is formed above the recessed channel region by repeating an oxidation method and a deposition method a predetermined number of times.

18. The method of claim 17, wherein the oxidation method is a thermal oxidation method.

19. The method of claim 17, wherein the deposition method is a chemical vapor deposition method.

20. The method of claim 17, wherein an oxidation film is formed above the recessed channel region and has a substantially uniform thickness.
